(19) United States
(12) Patent Application Publication
(10) Pub. No.: US 2011/0254898 A1
(43) Pub. Date: Oct. 20, 2011

(54) LIQUID DISCHARGE HEAD AND METHOD FOR MANUFACTURING THE SAME

(75) Inventors: Chiaki Muraoka, Kawaguchi-shi (JP); Yukuo Yamaguchi, Tokyo (JP)

(73) Assignee: CANON KABUSHIKI KAISHA, Tokyo (JP)

(21) Appl. No.: 13/086,205

(22) Filed: Apr. 13, 2011

(30) Foreign Application Priority Data
Apr. 15, 2010 (JP) 2010-094082
Jan. 5, 2011 (JP) 2011-000638

(51) Int. Cl. B41J 2/14; H01L 21/28

(52) U.S. Cl. 347/50; 438/21; 257/E21.191

(57) ABSTRACT

A liquid discharge head includes an electric contact electrically connected with a liquid discharge device; a first semiconductor substrate having an energy generation element for generating energy to discharge a liquid, and a driver unit including a first transistor and configured to drive the energy generation element; and a second semiconductor substrate having a receiving unit configured to possess a second transistor and receive a signal serially transmitted via the electric contact, and an expansion unit configured to possess a third transistor and parallel-convert the signal received in the receiving unit to generate a signal to control the driver unit, wherein a gate oxide film in the first transistor is thicker than a gate oxide film in the second transistor and a gate oxide film in the third transistor.

### BACKGROUND OF THE INVENTION

1. Field of the Invention

The present invention relates to a liquid discharge head for discharging a liquid and a method for manufacturing the same.

2. Description of the Related Art

An inkjet recording apparatus (hereinafter, referred to as recording apparatus) is an apparatus to discharge ink and perform recording on a recording medium using a representative inkjet recording head (hereinafter, referred to as recording head) as a liquid discharge head.

In improvement of the performance of this recording apparatus, in order to increase a recording speed, the number of ink discharge ports on the recording head and the recording frequency are enhanced. Further, to stabilize an image quality, the recording apparatus transmits and receives a control signal between a main body control unit provided on a recording apparatus main body and a recording element driving unit for driving a recording element provided on the recording head, and controls the state of ink discharge. The detail of this control includes, for example, monitoring the temperature of the recording head to drive the recording head on a more suitable condition, adjusting the recording head and the ink to the predetermined temperature to stabilize the quantity of ink discharge, and the like.

Such development of the recording apparatus increases the volume of data transmitted from the main body control unit provided on the recording apparatus to the recording head. Accordingly, the number of wires through which data is transmitted needs to be necessarily increased. Thus, when the number of contact terminals on the recording head used to electrically connect with the main body control unit is increased, this results in a large recording head.

When wiring is disposed at high densities to avoid the large recording head, in the wiring, noise is easily generated. Thus, it is feared that it influences stable driving of the recording head. As a method to solve such the issue, it is effective to adopt a low voltage differential transmission method for transmitting serial data at high speed, as shown in a recording apparatus discussed in US Patent Publication No. 2002/0105554. By using this low voltage differential transmission method, the number of wires and generation of noise can be reduced, and the influence of noise on signal transmission can be decreased. Accordingly, a high transmission speed can be achieved.

FIG. 13 is a block diagram illustrating an example of the configuration of control between a general recording apparatus main body and a recording element substrate on a recording head. The recording element substrate includes a recording element driving unit 56 comprising a recording element and a driver unit for driving the recording element, and a receiving unit and an expansion unit 57 configured to receive data from the recording apparatus main body to transmit it to the recording element driving unit. When the data serially transmitted from the main body control unit is parallel-converted and transmitted to the recording element driving unit 56, the number of contact terminals for connecting the recording apparatus main body and the recording head can be reduced.

In order to achieve high-speed data transmission in the above-described configuration, it is required that receiving of serial data in a receiving unit and parallel conversion in an expansion unit are performed at a high speed. In order to speed up these processing, it is important to speed up the operation speed of transistors that constitute the receiving unit and the expansion unit. The transistors that constitute the receiving unit and the expansion unit are, for example, an enhancement type N-channel metal oxide semiconductor (NMOS) transistor. In order to increase the operation speed of this transistor, it is effective to thin the thickness of a gate oxide film and hence reduce an operation threshold voltage of the transistor.

On the other hand, a transistor having a configuration similar to these transistors is also used in a transistor that constitutes the driver unit on the recording element driving unit 56. However, the transistor that constitutes the driver unit for driving the recording element is significantly higher in applied voltage than the transistor that constitutes the receiving unit and the expansion unit 57. Thus, it is required for the transistor on the driver unit to secure pressure resistance against a higher applied voltage. To improve the pressure resistance, it is effective to thicken the thickness of the gate oxide film.

Therefore, the required thickness of the gate oxide film in the transistor is different between a case of the speedup of a data transmission and an increase in the pressure resistance. When thickness of the gate oxide film in the transistor that constitutes each circuit is different, a manufacturing process may be complicated and a cost may be increased. On the other hand, when the gate oxide film in the transistor that constitutes each circuit is formed on the recording element substrate using a forming process similar to that when a semiconductor is manufactured, the gate oxide film is normally formed in the same thickness. Accordingly, both performances of speedup of the data transmission and the increase in the pressure resistance may not sufficiently be compatible.

### SUMMARY OF THE INVENTION

The present invention is directed to a liquid discharge head which can easily be manufactured, and copes with both speedup of a data transmission speed and an increase in pressure resistance.

According to an aspect of the present invention, a liquid discharge head includes an electric contact electrically connected with a liquid discharge device; a first semiconductor substrate having an energy generation element for generating energy to discharge a liquid, and a driver unit including a first transistor and configured to drive the energy generation element; and a second semiconductor substrate having a receiving unit configured to have a second transistor and receive a signal serially transmitted via the electric contact, and an expansion unit configured to have a third transistor and parallel-convert the signal received in the receiving unit to generate a signal to control the driver unit, wherein a gate oxide film in the first transistor is thicker than a gate oxide film in the second transistor and a gate oxide film in the third transistor.

According to the present invention, a liquid discharge head can be provided which can be easily manufactured, and can achieve both speedup of a data transmission and an increase in pressure resistance.

Further features and aspects of the present invention will become apparent from the following detailed description of exemplary embodiments with reference to the attached drawings.

### BRIEF DESCRIPTION OF THE DRAWINGS

The accompanying drawings, which are incorporated in and constitute a part of the specification, illustrate exemplary embodiments, features, and aspects of the invention and, together with the description, serve to explain the principles of the invention.

FIG. 1 is a diagram illustrating a connection between a wire and a contact terminal on a recording head according to the present invention.

FIG. 2 is a diagram illustrating the whole configuration of a recording apparatus incorporated with a recording head according to the present invention.

FIG. 3 is a block diagram illustrating the configuration of control between a recording head and a recording apparatus main body according to the present invention.

FIG. 4 is a diagram illustrating data transmission using a differential transmission method in a recording head according to the present invention.

FIG. 5 is a diagram illustrating the configuration of a circuit of a recording element substrate on a recording head according to the present invention.

FIGS. 6A and 6B are diagrams illustrating the configuration of a recording head according to a first exemplary embodiment of the present invention.

FIGS. 7A and 7B illustrate the configuration of a carriage unit on a recording apparatus incorporated with a recording head according to a first exemplary embodiment of the present invention.

FIG. 8 is an external view illustrating the configuration of a recording head according to a second exemplary embodiment of the present invention.

FIG. 9 is an exploded view illustrating the configuration of a recording head according to a second exemplary embodiment of the present invention.

FIG. 10 is an external view illustrating the configuration of a recording head according to a third exemplary embodiment of the present invention.

FIG. 11A is a diagram illustrating the configuration of a transistor provided on a control substrate and FIG. 11B is a diagram illustrating the structure of a transistor provided on a recording element substrate.

FIG. 12 is a block diagram illustrating the configuration of an internal circuit on a control substrate.

FIG. 13 is a block diagram illustrating the configuration of control between a conventional recording apparatus and a recording head.

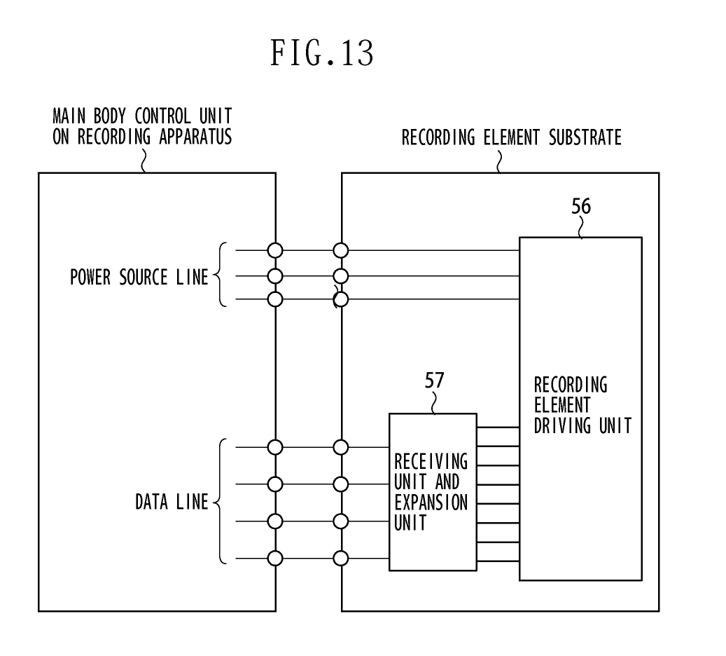

### DESCRIPTION OF THE EMBODIMENTS

Various exemplary embodiments, features, and aspects of the invention will be described in detail below with reference to the drawings.

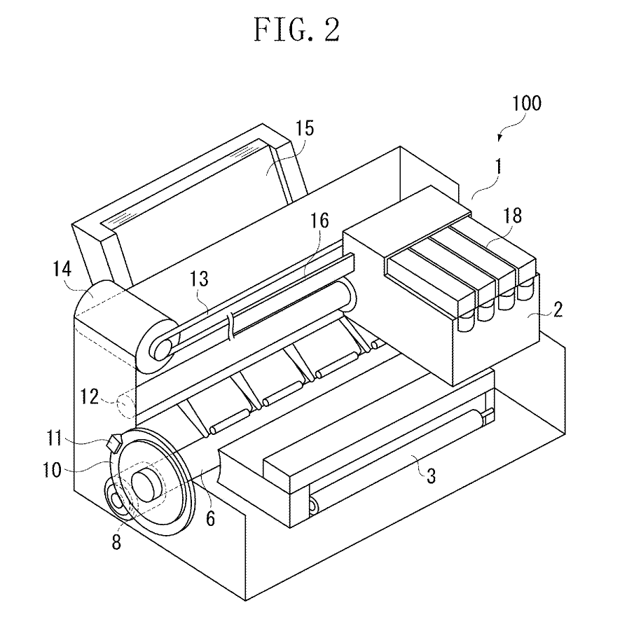

First, referring to FIG. 2, the principal configuration of an inkjet recording apparatus 100 (hereinafter, referred to as recording apparatus) as a liquid discharge apparatus on which an inkjet recording head 1 (hereinafter, referred to as recording head 1) as a liquid discharge head according to the present invention is mounted will be described.

The recording head 1 has a discharge port array including a plurality of discharge ports for discharging ink. A carriage 2 on which this recording head 1 is mounted is engaged with a shaft 12 and scans in a direction orthogonal to a direction in which a recording medium 15 is conveyed. The carriage 2 receives a driving force from a motor 14 via a belt 13. Thus, the carriage 2 performs scanning. A carriage encoder 16 is detected by a carriage position sensor (not illustrated), whereby the position of the carriage 2 is detected.

When a recording operation is started, the recording medium 15 such as a paper is conveyed by a paper feed roller 6 which is driven by a paper feed motor 8. A sensor 11 detects a slit provided in a paper feed encoder 10 that rotates in synchronization with the paper feed motor 8, whereby the position of the recording medium 15 is detected.

The recording medium recorded with ink discharged from the recording head 1 is conveyed outside the recording apparatus 100 with rotation of a paper discharge roller 3.

Each timing of driving of the recording head 1 for discharging ink form the discharge port on the recording head 1, scanning of the carriage 2, and conveyance of the recording medium 15 is controlled. Thus, ink is discharged in a predetermined position of the recording medium 15.

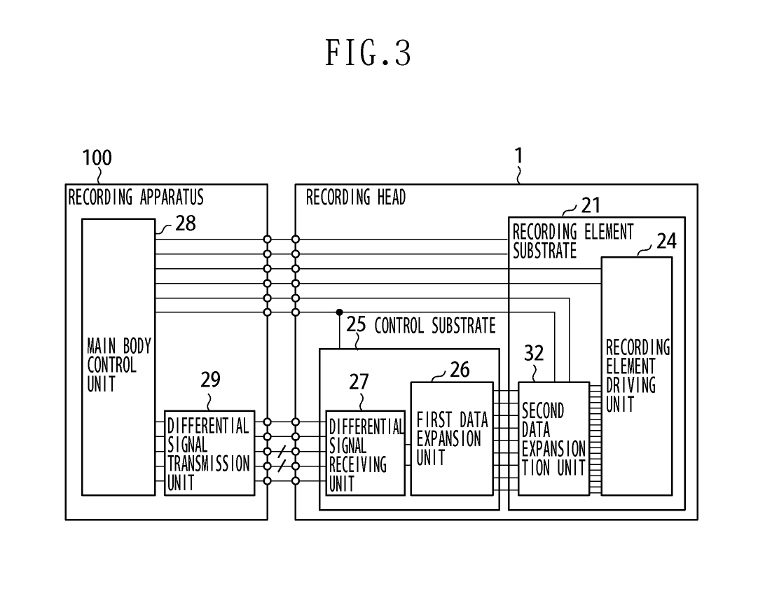

FIG. 3 is a block diagram illustrating the configuration of a control system between the recording apparatus 100 main body on which the recording head 1 is mounted and the recording head 1.

The recording head 1 is driven based on a signal generated in a main body control unit 28 on the recording apparatus 100 main body. The recording head 1 includes a recording element substrate 21 as a first semiconductor substrate and a control substrate 25 as a second semiconductor substrate. These are semiconductor integrated circuit chips provided as a separated body.

The recording element substrate 21 includes a recording element 23 as an energy generation element for generating energy to discharge ink from a discharge port of the recording head 1. A recording element driving unit 24 mounted on the recording element substrate 21 is a circuit containing the recording element 23 and a transistor 24a for driving the recording element 23. As the recording element 23, a heater or a piezoelement can also be used.

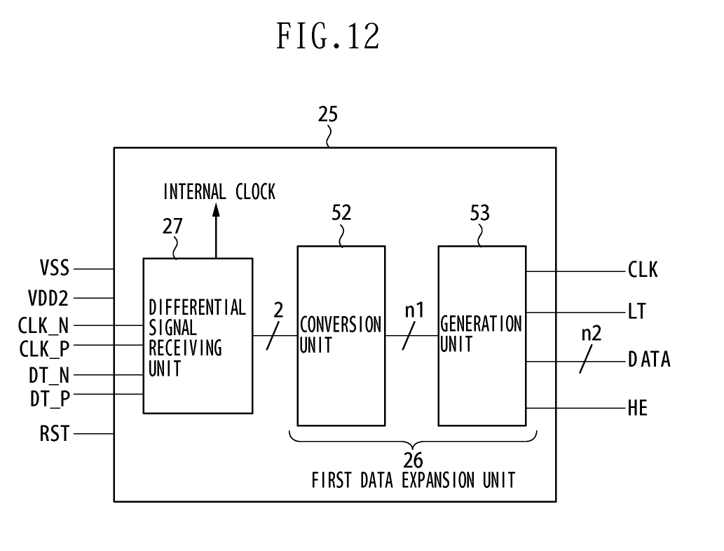

A block diagram illustrating the configuration of an internal circuit on the control substrate 25 is shown in FIG. 12. The control substrate 25 includes a differential signal receiving unit 27 configured to receive a signal serially transmitted from the main body control unit 28 via a differential signal receiving unit 27 by a low voltage differential transmission method and a first data expansion unit 26 configured to parallel-convert the received signal to generate a signal to be transmitted to the recording element substrate 21. The first data expansion unit 26 contains a circuit having different roles such as a conversion unit 52 configured to perform parallel conversion of a signal and a generation unit 53 configured to generate a serial signal based on the converted signal.

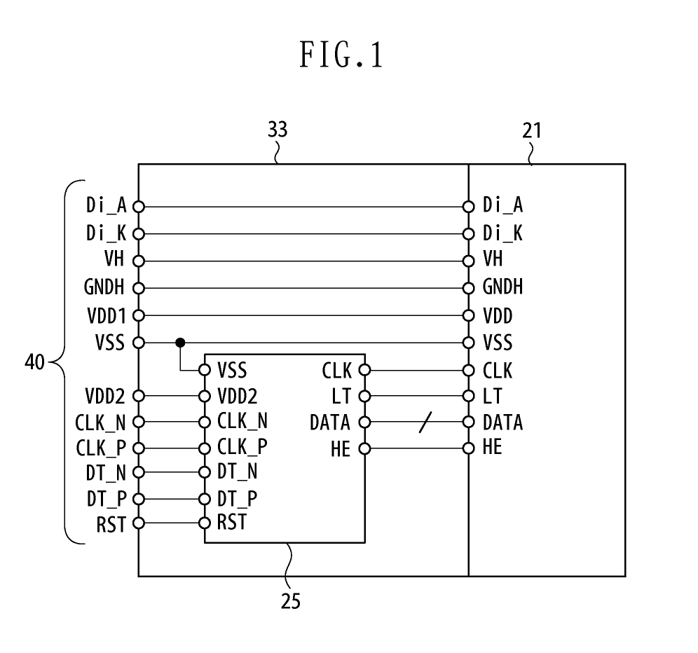

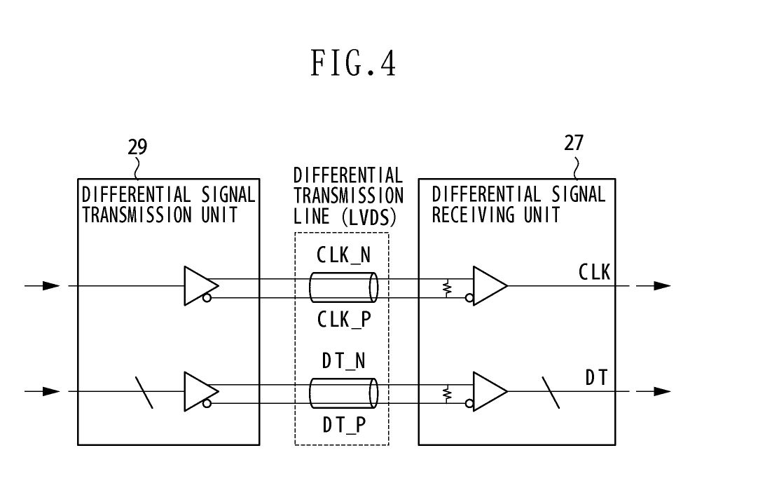

A signal to be transmitted to the control substrate 25 by the low voltage differential transmission method is a clock signal (CLK_N and CLK_P) and a data signal (DT_N and DT_P). A differential signal transmission unit 29 and the differential signal receiving unit 27 are connected as illustrated in FIG. 4. Among wires which are connected to the recording element substrate 21, a power source (VH) wire, a grand (GNDH) wire, or a wire for an element which is controlled in units of time longer than that of a data signal is electrically connected to the recording element substrate 21 without passing through the differential signal transmission unit 29 and the control substrate 25 (refer to FIG. 1).

The clock signal (CLK_N and CLK_P) are used for synchronization with not only serial transmission between the recording apparatus 100 and the recording head 1 but also data processing in the differential signal receiving unit 27 and the first data expansion unit 26 in the control substrate 25. Such configuration need not include a transmission element or a transmitter for generating a clock on the recording element substrate 21 on the recording head 1 and results in a reduction in noise and cost.

The detail of specific data processing to be performed in an internal circuit on the control substrate 25 will be described below.

FIG. 1 illustrates terminals contained in the recording head 1 and wiring provided on the recording head 1.

Electric power and signals are supplied from the recording apparatus 100 main body to the recording head 1 via a contact terminal 40 as an electric contact. The recording head 1 is detachably attached to the carriage 2 on the recording apparatus 100. With the recording head 1 mounted on the carriage 2, the recording apparatus 100 and the recording head 1 are electrically connected via the contact terminal 40 provided on the recording head 1. Each of the contact terminal 40, the control substrate 25, and the recording element substrate 21 is mutually electrically connected by a wire within a wiring member 33. In the present exemplary embodiment, a flexible wiring member is used as the wiring member 33. However, the wiring member 33 is not limited to this.

Each of a terminal Di_A to a terminal VSS on the contact terminal 40 is connected to the corresponding terminal on the recording element substrate 21. The terminal Di_A and the terminal Di_K are terminals to monitor the temperature of a temperature detection unit in the recording element substrate 21 and the recording element substrate 21. On the temperature detection unit, a diode is equipped as a temperature sensor. A terminal VH and a terminal GNDH are a terminal for a power source to apply a voltage to the recording element 23 provided on the recording element substrate 21 and a terminal for the ground corresponding to this terminal. A terminal VDD1 and a terminal VSS are a terminal for a power source of a logic signal to be used inside the recording element substrate 21 and a terminal for the ground corresponding to this terminal.

Each of a terminal VDD2 to a terminal RST on the contact terminal 40 is connected to the corresponding terminal on the control substrate 25.

Terminals CLK_N, CLK_P, DT_N, and DT_P are terminals for use in low voltage differential transmission. The terminals CLK_N and CLK_P transmit a clock signal to the control substrate 25. The terminals DT_N and DT_P transmit a data signal to the control substrate 25. The terminal RST is a terminal to receive a signal for reset of data in the control substrate 25. The terminal VDD2 is a terminal for a power source of a logic signal for use in the control substrate 25. The terminal VSS is used for the ground corresponding to this terminal.

Terminals CLK, LT, DATA, and HE provided on the control substrate 25 are connected with the recording element substrate 21.

The terminal CLK is a terminal to transmit a clock signal to be generated by dividing a clock signal received via the terminals CLK_N and CLK_P, to the recording element substrate 21. This clock signal is lower in frequency than a clock signal to be transmitted via the terminals CLK_N and CLK_P.

The terminal DATA is a terminal to transmit a plurality of data signals to be generated by parallel-converting a data signal received via the terminals DT_N and DT_P. Accordingly, the number of terminal DATA on the recording element substrate 21 side is more than the total number of terminals DT_N and DT_P on the control substrate 25 side.

The terminal LT is a terminal to transmit a latch signal for temporarily storing and retaining data when a data signal transmitted into the recording element substrate 21 via the terminal DATA is further decoded and divided.

The terminal HE is a terminal to transmit a heat enabling signal that determines time to apply energy to the recording element 23.

Next, data processing to be performed in an internal circuit on the control substrate 25 will be described referring to FIG. 12.

First, the differential signal receiving unit 27 separates a data signal (DT_N and DT_P) transmitted by the low voltage differential transmission method. More particularly, a data signal to be transferred when a clock rises and a data signal to be transferred when a clock drops are output using a separate signal line. Further, the differential signal receiving unit 27 converts a data signal received in a low voltage amplitude (e.g.,200 mV) into a signal level (e.g., 3.3 V) which is used in the control substrate 25 to transmit the data signal to the conversion unit 52. The data signal output to two signal lines is parallel-converted into n1 data signals in the conversion unit 52. Thereafter, a plurality of serial data according to a format in the recording element substrate 21 is regenerated from the data signal transmitted from the conversion unit 52 in the generation unit 53 to transmit it to a second data expansion unit 32 (logic unit) on the recording element substrate 21. This processing also generates a clock signal (CLK) for synchronization with data processing in an internal circuit on the recording element substrate 21 and a latch signal LT to be transmitted to a latch circuit in the recording element substrate 21. The number of signal lines for transmitting a data signal between these internal circuits is two lines between the differential signal receiving unit 27 and the conversion unit 52, n1 lines between the conversion unit 52 and the generation unit 53, and n2 lines between the generation unit 53 and the first data expansion unit 26. An inequality 2<n2<n1 holds.

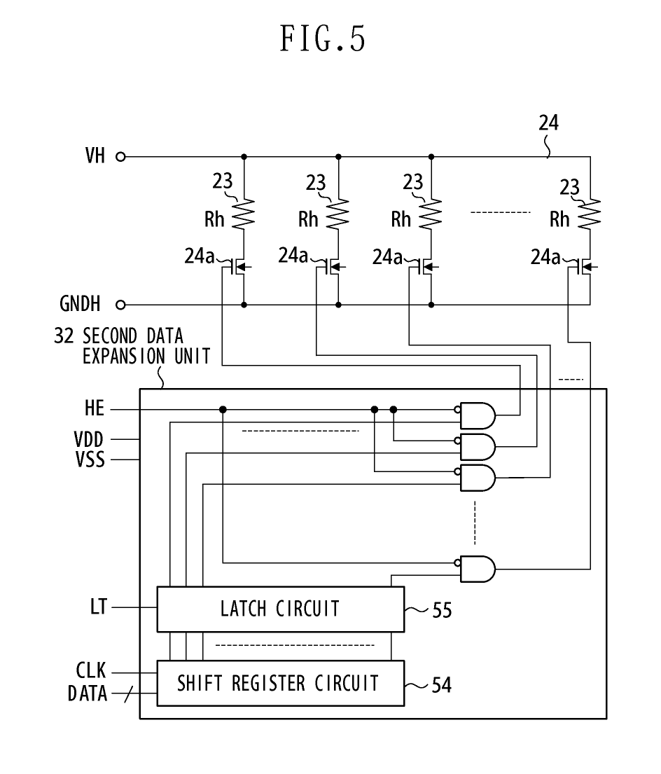

FIG. 5 illustrates the configuration of an internal circuit provided on the recording element substrate 21. On the recording element substrate 21, the recording element driving unit 24 and the second data expansion unit 32 are provided. The recording element driving unit 24 includes a plurality of recording elements 23 and the transistor 24a (first transistor) that constitutes a driver unit for driving the recording element 23 provided corresponding to the respective recording elements 23. The transistor 24a is a switch for controlling voltage application to the recording element 23. The second data expansion unit 32 includes a circuit having different roles such as a shift register circuit 54 and a latch circuit 55. A logic signal received from the generation unit 53 in the first data expansion unit 26 on the control substrate 25 via the respective terminals CLK, LAT, DATA, and HE is transmitted to the second data expansion unit 32.

VDD and VSS are a power source and the ground for the logic signal, and a voltage is supplied from the recording apparatus 100 without passing through the control substrate 25. VH and GNDH are a power source and the ground for driving the recording element 23. These are also supplied with a voltage from the recording apparatus 100 without passing through the control substrate 25. The voltage of the logic power source is, for example, 3.3 V. The voltage of the recording element driving power source is 24 V.

Next, flow to generate a signal for driving the recording element 23 in the second data expansion unit 32 will be described.

Serial data received from the generation unit 53 in the first data expansion unit 26 via the terminal DATA is transferred to the shift register circuit 54 in synchronization with the clock signal (CLK) transmitted via the terminal CLK. Data input to the shift register circuit 54 is stored in the latch circuit 55 based on input of the latch signal. This stored data and the heat enabling signal generated in the generation unit 53 on the first data expansion unit 26 are combined. Thus, a pulse signal to be input to the transistor 24a is generated. The transistor 24a controls voltage application to the recording element 23 based on this pulse signal. Time to apply a voltage to the recording element 23 is controlled by a pulse width of the pulse signal generated in the second data expansion unit 32. By applying a voltage to the recording element 23, the recording element 23 is driven, energy to discharge ink in the recording head 1 is generated, and ink discharge, in other words, image recording is performed.

When the recording element substrate 21 deals with recording of a plurality of colors, a group of the recording element 23 is divided for each color and a different DATA terminal is provided for each group.

As described above, in the recording head 1 in the present exemplary embodiment, the control substrate 25 including the differential signal receiving unit 27 configured to receive a differential signal and the first data expansion unit 26 configured to parallel-convert the received data, and the recording element substrate 21 including the recording element driving unit 24 are a semiconductor substrate of a separate body.

A transistor 27a (second transistor) that constitutes the differential signal receiving unit 27 and a transistor 26a (third transistor) that constitutes the first data expansion unit 26 are formed in the forming process, each gate oxide film of which is the same. As illustrated in FIG. 12, the first data expansion unit 26 has a circuit having different roles such as the conversion unit 52 and the generation unit 53. Accordingly, the transistor 26a that constitutes the first data expansion unit 26 is constituted by separate transistors provided in different circuits. The transistor 26a denotes a transistor 52a that constitutes the conversion unit 52 and a transistor 53a that constitutes the generation unit 53.

Further, a transistor 24a (first transistor) that constitutes the driver unit on the recording element driving unit 24 and a transistor 32a (fourth transistor) that constitutes the second data expansion unit 32 are formed in the forming process, each gate oxide film of which is the same. As described above, in the present exemplary embodiment, the second data expansion unit 32 has a circuit having different roles such as the shift register circuit 54 and the latch circuit 55. Accordingly, the transistor 32a that constitutes the second data expansion unit 32 is constituted by separate transistors provided in the different circuit. The transistor 32a that constitutes the second data expansion unit 32 denotes a shift register circuit transistor 54a that constitutes the shift transistor circuit 54 and a latch circuit transistor 55a that constitutes the latch circuit 54.

As described above, on one semiconductor substrate, the gate oxide film is formed in the same forming process. Thus, the complexity of the manufacturing process can be prevented and a low cost can be achieved.

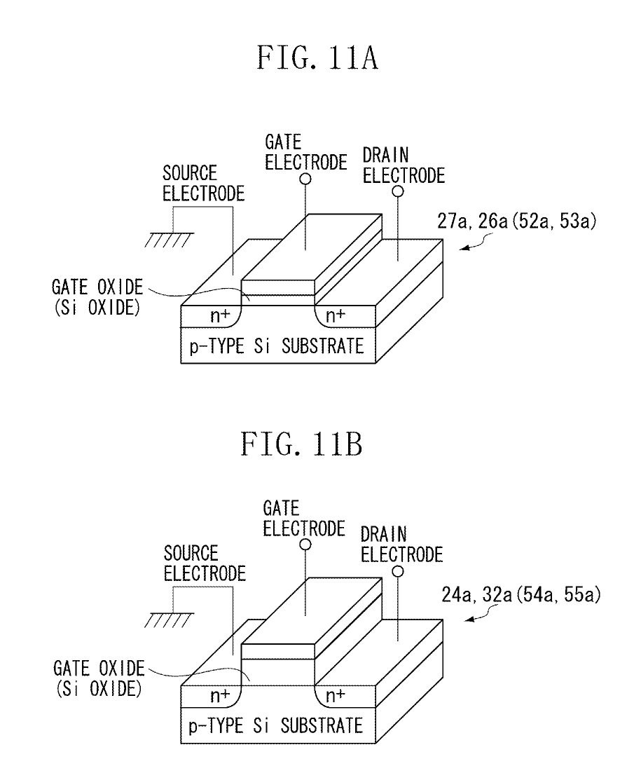

In both of the control substrate 25 and the recording element substrate 21, an enhancement type NMOS transistor is used. In FIG. 11A, the structure of the transistor 27a that constitutes the differential signal receiving unit 27, the transistor 52a that constitutes the conversion unit 52, and the transistor 53a that constitutes the generation unit 53 is illustrated. These are transistors provided in different three circuits. However, since these may be the same configuration, in FIG. 11A, these are illustrated by one drawing.

In FIG. 11B, the structure of the transistor 24a, the shift register circuit transistor 54a, and the latch circuit transistor 55a that constitute the driver unit in the recording element driving unit 24 provided on the recording element substrate 21. These are transistors provided in different three circuits. However, since these may have the same configuration, in FIG. 11B, they are illustrated by one drawing. Since in the transistors formed on the control substrate 25, the gate oxide film is formed in the same forming process, each of the thickness of the gate oxide film in the transistors 27a, 52a, and 53a in the control substrate 25 is the same. Further, since in the transistors formed on the recording element substrate 21, the gate oxide film is formed in the same forming process, each of the thickness of the gate oxide film in the transistors 24a, 54a, and 55a in the recording element substrate 21 is the same.

As illustrated in FIG. 11, the thickness of the gate oxide film in the transistors 24a and 32a (54a and 55a) in the recording element substrate 21 is thicker than the thickness of the gate oxide film in the transistors 27a and 26a (52a and 53a) in the control substrate 25. This reason will be described below.

Data processing in the control substrate 25 is performed at a significantly high speed in synchronization with a clock signal transmitted from the terminals CLK_N and CLK_P. On the other hand, data processing in the recording element substrate 21 is performed in synchronization with a clock signal to be transmitted via the terminal CLK provided on the control substrate 25 and at a speed by a few degrees lower than a speed in the control substrate 25. The frequency of a base clock in data receiving and expansion processing to be performed in the control substrate 25 is, for example, the order of 100 MHz, whereas the frequency of a base clock in data processing to be performed in the recording element substrate 21 is, for example, the order of 10 MHz.

In order to increase the speed of data signal processing, an operation speed of a transistor needs to be increased. In order to increase the operation speed of the transistor, it is useful to thin the gate oxide film, thereby lowering the operation threshold voltage of the transistor. For example, the thickness of the gate oxide film in the transistor in the control substrate 25, which can deal with data receiving and expansion processing at an operation frequency of 100 MHz, is the order of 75 angstroms. The thickness of the gate oxide film in the transistor in the recording element substrate 21, which can deal with data processing at an operation frequency of 10 MHz, is the order of 600 angstroms.

On the other hand, from the viewpoint of pressure resistance, when a voltage to be applied to a transistor is high, it is useful that a gate oxide film is thick. A voltage to be applied to the recording element driving unit 24 provided on the recording element substrate 21 is significantly higher than a voltage to be applied to the differential signal receiving unit 27 and the first data expansion unit 26 provided on the control substrate 25. For example, the voltage to be applied to the differential signal receiving unit 27 and the first data expansion unit 26 is 3.3 V. The voltage to be applied to the recording element driving unit 24 is 20 V or higher.

In the recording head 1 in the present exemplary embodiment, the control substrate 25 and the recording element substrate 21 are provided as semiconductor substrates of a separate body. Thus, even when on the respective semiconductor substrates, a gate oxide film of a transistor is formed in the same forming process, the gate oxide film of the transistor satisfying the requirement of a circuit provided on the respective semiconductor substrates can be formed. Specifically, the transistors 27a, 52a, and 53a in the control substrate 25 prioritize the speedup of a data processing speed. Thus, the gate oxide film can be thinned. On the other hand, the transistor 24a that constitutes the recording element driving unit 24 in the recording element substrate 21 prioritizes securing of pressure resistance against a high voltage. Thus, the gate oxide film can be thickened. Particularly, the gate oxide film in the transistor provided on the control substrate 25 can be thinned. Thus, when data is transmitted at a high speed using the low voltage differential method, high-speed data processing can be carried out using sufficiently its performance.

In order to perform data processing in the recording element substrate 21 even at a low operation frequency, the first data expansion unit 26 provided on the control substrate 25 divides a data signal input in the recording element substrate 21 into the predetermined number of lines or more. The level of this data division may be optimized in consideration of the number of recording elements 23, the driving frequency of the recording element 23, the thickness of the gate oxide film of the transistor in the recording element substrate 21, and the like.

In the configuration as described above, a logic signal can be serially transmitted at high speed between the main body control unit 28 on the recording apparatus 100 and the control substrate 25 by the low voltage differential transmission method. Further, transmission between the control substrate 25 and the recording element substrate 21 is synchronized with the divided clock and also the number of data lines is increased by parallel conversion. Thus, data can be transmitted and received by low speed transmission. Thus, data transmission at higher speed can be realized while securing pressure resistance of a transistor in the recording element substrate 21.

As described above, the low voltage differential transmission method is used for data transmission between the recording apparatus 100 and the recording head 1. Thus, generation of noise is suppressed to be small even if data transmission is highly speeded up. Further, even if noise is generated, the influence hardly results in a decrease in reliability of signal transmission. Accordingly, a data transmission speed between the recording apparatus 100 and the recording head 1 can be highly speeded up without increasing the number of contact terminals. Since the number of contact terminals is not increased, as a result, a small-sized recording head 1 can be provided.

Furthermore, when a heat generation element such as a heater is used as the recording element 23, the temperature of the recording element substrate 21 rises. However, this reduces a maximum transmission speed of a transistor. Thus, the upper limit of the transmission speed may be reduced. Accordingly, as described above, when the recording element substrate 21 and the control substrate 25 are configured as a separate body, the influence of temperature on the control substrate 25 by the recording element 23 can be reduced and high-speed data transmission can be performed.

In the above description, the heat enable signal is generated from data transmitted from the recording apparatus 100 via the terminals DT_N and DT_P in the first data expansion unit 26. However, the heat enable signal may also be generated in the second data expansion unit 32. A method for dividing a data expansion level in the first data expansion unit 26 and the second data expansion unit 32 may be optimized in consideration of the balance of the data processing speed in the control substrate 25 and the recording element substrate 21.

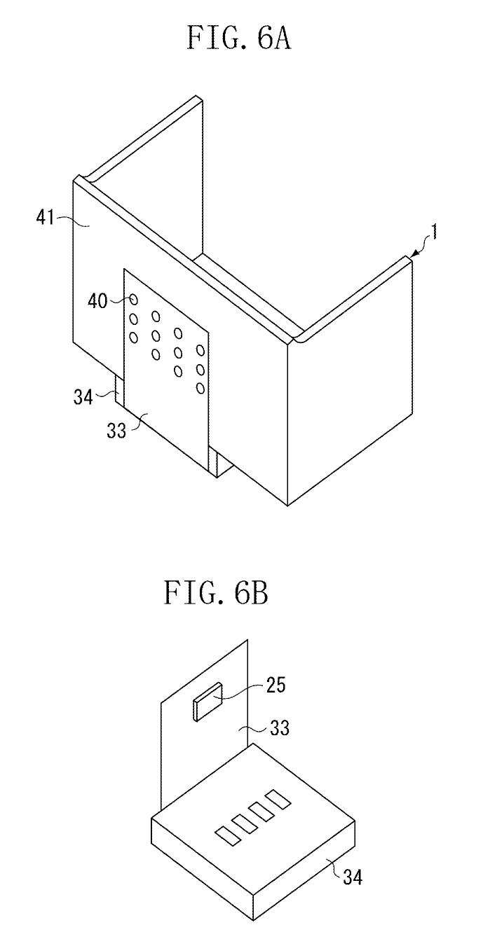

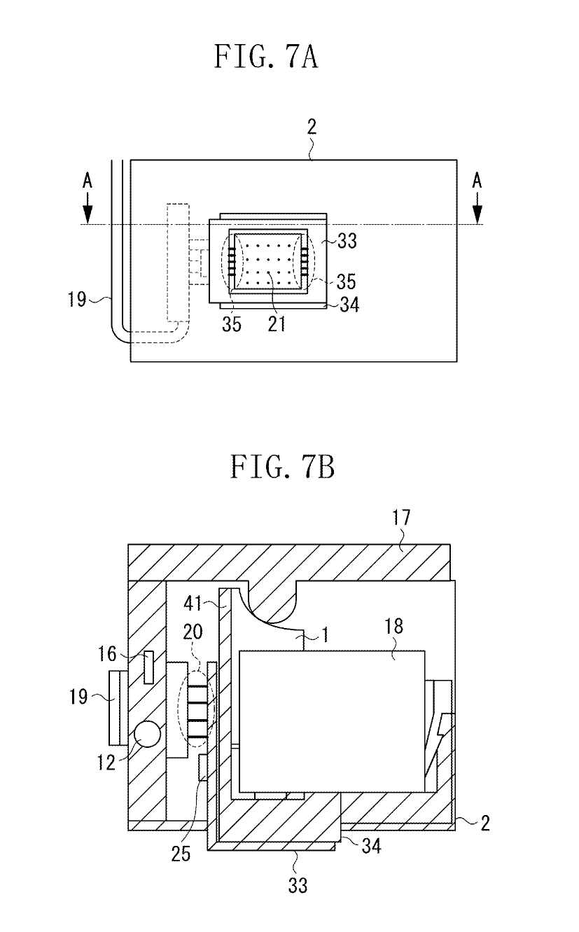

The recording head 1 according to a first exemplary embodiment of the present invention will be described. FIG. 6A illustrates an external view of the recording head 1 removed from the recording apparatus 100. FIG. 6B illustrates an exploded view of the recording head 1 removed from a housing 41. FIG. 7A illustrates a bottom view of the recording head 1 mounted on the carriage 2. FIG. 7B illustrates a cross sectional view taken on line A-A of FIG. 7A.

The contact terminal 40, which electrically connects with the recording apparatus 100, is integrally formed with wires within the wiring member 33a and provided on the exposed outer face of the recording head 1. Further, the control substrate 25 is provided on the housing 41 side of the wiring member 33 and provided inside the recording head 1, not to be exposed to the outside. The control substrate 25 is electrically connected to wires within the wiring member 33. Furthermore, the recording element substrate 21 provided on the vertically lower face (bottom face) of the recording head 1 is also electrically connected to wires in the wiring member 33.

A wiring layer of the wiring member 33 may be a single layer structure or a plurality of layers structure. However, if the plurality of layers structure is employed, the degree of freedom of the alignment order of terminals increases and electrically more suitable arrangement can be provided in the wiring that connects the control substrate 25 and the recording element substrate 21.

As illustrated in FIG. 7, the recording head 1 is detachably attached to the carriage 2. With the recording head 1 attached to the carriage 2, the recording head 1 is fixed on the carriage 2 by a head fixing member 17. When the recording head 1 is attached and fixed on the carriage 2, the contact terminal 40 provided on one face in the side exposed to the outside of the recording head 1 is brought into contact with a contact pin 20 provided on the carriage 2, and electric connection between the recording head 1 and the recording apparatus 100 is performed. The contact pin 20 is connected with the main body control unit 28 on the recording apparatus 100 via a flexible cable 19.

The recording element substrate 21 is fixed on a support member 34. The contact terminal 40 and the recording element substrate 21 are electrically connected via the wiring member 33 and a lead 35 provided on the wiring member 33. An ink tank 18 is detachably attached to the recording head 1. With the ink tank 18 attached, ink can be supplied to a discharge port provided on the recording element substrate 21.

The control substrate 25 is provided on the back of the face on which the contact terminal 40 of the wiring member 33 is provided. Thus, an electric connection unit of the wiring member 33 connecting with the recording apparatus 100 can be miniaturized. Further, since function of the control substrate 25 is increased and or multi-functionality is achieved, even when the control substrate 25 becomes large in size, the possibility that the electric connection unit of the wiring member 33 connecting with the recording apparatus 100 becomes large in size can be reduced.

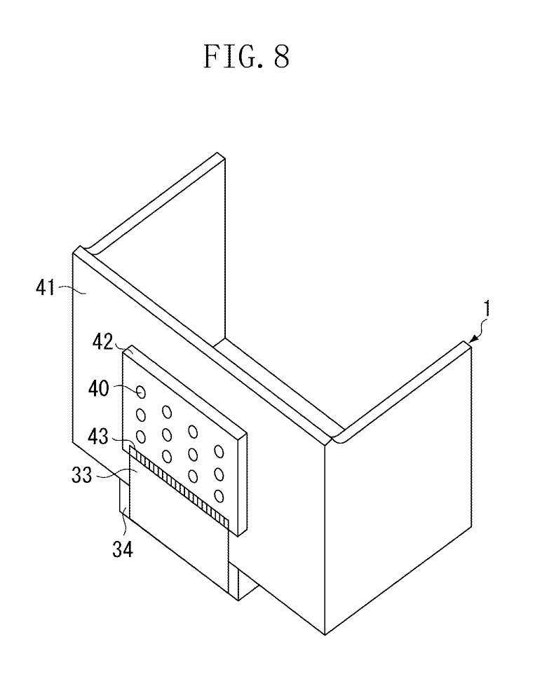

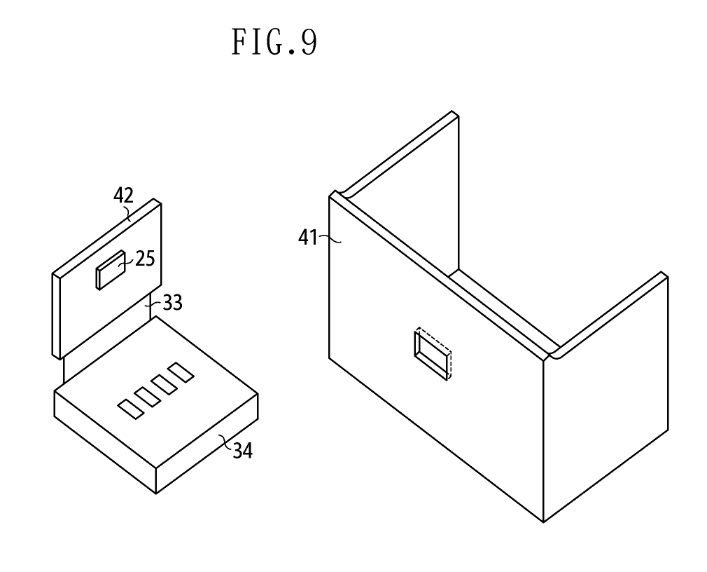

The recording head 1 according to a second exemplary embodiment of the present invention will be described. FIG. 8 illustrates an external view of the recording head 1 removed from the recording apparatus. Further, FIG. 9 illustrates an exploded view of the recording head 1 with the housing 41 removed from the recording head 1.

In the present exemplary embodiment, the contact terminal 40 and the control substrate 25 are provided on a contact substrate 42 made of a rigid substrate showing higher rigidity than the wiring member 33 which is a flexible wiring member. The contact terminal 40 is provided on the face of the contact substrate 42 in the side to be connected with the contact pin 20 of the cartridge 2. The control substrate 25 is provided on the back of the face on which the contact terminal 40 is provided.

The contact substrate 42 and the wiring member 33 are electrically connected by an electric connection unit 43. The contact substrate 42 and the recording element substrate 21 provided on the vertical lower face (bottom face) of the recording head 1 are electrically connected via the wiring member 33.

On the contact substrate 42, a plurality of wiring layers is laminated. Wires that connect between the contact terminal 40 and the control substrate 25, and between the contact terminal 40 and the electric connection unit 43, are three-dimensionally wired combining a planar wiring layout and a through-hole provided in the contact substrate 42.

The portion of the housing 41 on the recording head 1, which corresponds to the control substrate 25, is provided with a recess. This recess serves as a space to store the control substrate 25. With the contact substrate 42 fixed on the housing 41, the control substrate 25 is in the state of being surrounded by the housing 41 and the contact substrate 42.

The control substrate 25 is provided on the back of the face on which the contact terminal 40 of the contact substrate 42 is provided, so that the contact substrate 42 can be miniaturized. Further, even when the size of the control substrate 25 becomes large if the control substrate 25 obtains high functionality or multi-functionality, the possibility of the large contact substrate 42 can be reduced.

Since the control substrate 25 is provided on the contact substrate 42 which is a rigid substrate showing high rigidity, the possibility that the electric connection unit between the contact substrate 42 and the control substrate 25 is easily deformed can be reduced and electric reliability can be improved. Further, the control substrate 25 is provided inside the recording head 1 without exposing it to the outside. Thus, the possibility that an ink mist or the like during recording adheres to the electric connection unit on the control substrate 25 can be reduced and electric reliability of the recording head 1 can be improved.

With respect to a position where the control substrate 25 is provided, it is desirable to provide the control substrate 25 such that the center position of the control substrate 25 is shifted away more from the electric connection unit 43 than the center position of the contact substrate 42. Since this causes a space between the control substrate 25 and the electric connection unit 43 to enlarge, even if the alignment order of the terminals on the control substrate 25 and the alignment order of the electric connection unit 43 are different, an increase in wiring resistance can be suppressed.

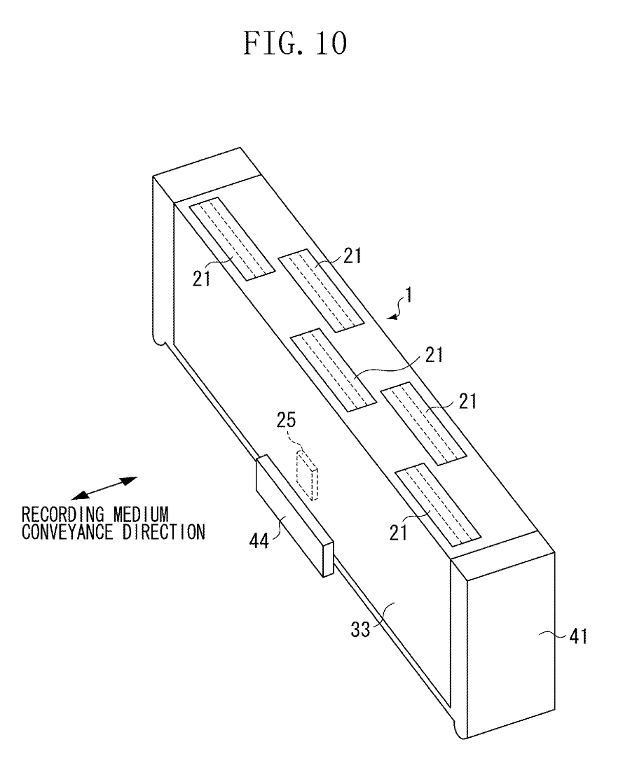

A third exemplary embodiment of the present invention will be described. The above-described exemplary embodiment can also be applied to a line-type recording head in which a plurality of recording element substrates 21 is arranged in a direction of arrangement of discharge ports illustrated in FIG. 10 (direction orthogonal to recording medium conveyance direction). The recording head 1 is electrically connected with the main body control unit 28 via a connector 44.

Generally, since in a recording head with a large number of discharge ports, the number of data is also increased, speedup of a data transmission is highly required. Thus, an effect due to introduction of the low voltage differential transmission method is large. Further, since a plurality of recording element substrates 21 can be controlled by one control substrate 25, a cost can be reduced compared with the housing in which the control substrate 25 is provided within the recording element substrate 21.

The above-described exemplary embodiment is configured to provide the control substrate 25 in a position where the control substrate 25 is not exposed to the outside of the recording head 1. However, the position where the control substrate 25 is provided is not particularly limited to this.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures, and functions.

This application claims priority from Japanese Patent Applications No. 2010-094082 filed Apr. 15, 2010 and No. 2011-000638 filed Jan. 5, 2011, which are hereby incorporated by reference herein in their entirety.

What is claimed is:

1. A liquid discharge head comprising:
an electric contact electrically connected with a liquid discharge device;
a first semiconductor substrate including an energy generation element for generating energy to discharge a liquid, and a driver unit having a first transistor and configured to drive the energy generation element; and
a second semiconductor substrate including a receiving unit configured to have a second transistor and receive a signal serially transmitted via the electric contact, and an expansion unit configured to have a third transistor and parallel-convert the signal received in the receiving unit to generate a signal to control the driver unit, wherein a gate oxide film in the first transistor is thicker than a gate oxide film in the second transistor and a gate oxide film in the third transistor.

2. The liquid discharge head according to claim 1, wherein the receiving unit receives a signal transmitted by a low voltage differential transmission method.

3. The liquid discharge head according to claim 2, wherein the first semiconductor substrate has a fourth transistor and includes a logic unit configured to generate a signal to control the driver unit based on the signal transmitted from the expansion unit, and
wherein the gate oxide film in the fourth transistor is thicker than the gate oxide film in the second transistor and the gate oxide film in the third transistor.

4. The liquid discharge head according to claim 1, wherein the second semiconductor substrate is provided in a position where it is not exposed to the outside.

5. The liquid discharge head according to claim 1, further comprising:
a contact substrate provided with the electric contact and the second semiconductor substrate; and
a wiring member for electrically connecting the contact substrate and the first semiconductor substrate,
wherein the contact substrate is higher in rigidity than the wiring member.

6. The liquid discharge head according to claim 5, further comprising:
a housing which includes a recess for storing the second semiconductor substrate and on which the contact substrate is fixed,
wherein the second semiconductor substrate is provided on the face of the contact substrate in the side to be fixed on the housing, and surrounded by the contact substrate and the housing.

7. The liquid discharge head according to claim 1, wherein the gate oxide film in the second transistor and the gate oxide film in the third transistor are formed on the second semiconductor substrate in the same forming process.

8. The liquid discharge head according to claim 3, wherein the gate oxide film in the first transistor and the gate oxide film in the fourth transistor are formed on the first semiconductor substrate in the same forming process.

9. A method for manufacturing a liquid discharge head according to claim 1 comprising:
forming the gate oxide film in the second transistor and the gate oxide film in the third transistor on the second semiconductor substrate in the same forming process.
